(19) United States
(12) Patent Application Publication
(10) Pub. No.: US 2025/0104791 A1
(43) Pub. Date: Mar. 27, 2025

(54) MEMORY DEVICE, TEST METHOD OF THE MEMORY DEVICE, AND METHOD OF MANUFACTURING MEMORY DEVICE INCLUDING THE TEST METHOD

(71) Applicant: Samsung Electronics Co., Ltd., Suwon-si (KR)

(72) Inventors: Jaewon Park, Suwon-si (KR); Jaehoon Lee, Suwon-si (KR); Kyomin Sohn, Suwon-si (KR)

(21) Appl. No.: 18/668,224

(22) Filed: May 19, 2024

(30) Foreign Application Priority Data
Sep. 27, 2023 (KR) 10-2023-0130894

(51) Int. Cl. G11C 29/18

(52) U.S. Cl. CPC G11C 29/18

(57) ABSTRACT

A memory device includes: a built-in self-test circuit configured to select a first target bank and a second target bank for each of a plurality of row addresses such that each of a plurality of memory banks is selected as the first target bank and the second target bank at least once, and to perform parallel tests on the first and second target banks for each of the plurality of row addresses; a comparator configured to compare first data output from the first target bank and second data output from the second target bank, and to output a fail signal according to a comparison result thereof; and a built-in analysis circuit configured to update a fail bank table indicating fail information of each of the plurality of memory banks, in response to the fail signal, and to determine a defective bank by referring to the fail bank table.

### CROSS-REFERENCE TO RELATED APPLICATION(S)

This application claims benefit of priority to Korean Patent Application No. 10-2023-0130894 filed on Sep. 27, 2023, in the Korean Intellectual Property Office, the disclosure of which is incorporated herein by reference in its entirety.

### BACKGROUND

The present disclosure relates to a memory device and a test method for the memory device.

A semiconductor memory device is manufactured through a semiconductor manufacturing process, and is then tested by testing equipment in a wafer, die or package state. A defective memory device may be selected through a test, and when some memory cells are defective, the memory device may be saved by performing a repair operation thereon. With micro-processing, the possibility of errors in a manufacturing process of a memory device such as a dynamic random access memory (DRAM) is increasing. In addition, errors may occur during a chip operation even if they were not detected in an initial test stage.

Accordingly, the importance of built-in self-test (BIST) of a memory device is increasing. As the capacitance of a memory device increases, an overhead may occur in order for the memory device to perform a self-test and analyze a test result thereof.

### SUMMARY

An aspect of the present invention is to provide a memory device for performing a self-test and reducing overhead for analyzing a test result, and a test method for the memory device.

According to an aspect of the present invention, a memory device includes: a plurality of memory banks each having a plurality of rows corresponding to a plurality of row addresses; a built-in self-test (BIST) circuit configured to select a first target bank and a second target bank for each of the plurality of row addresses such that each of the plurality of memory banks is selected as the first target bank and the second target bank at least once, and to perform parallel tests on the first target bank and the second target bank for each of the plurality of row addresses; a comparator configured to compare first data output from the first target bank and second data output from the second target bank, and to output a fail signal according to a comparison result thereof; and a built-in analysis circuit configured to update a fail bank table indicating fail information of each of the plurality of memory banks, in response to the fail signal, and to determine a defective bank by referring to the fail bank table.

According to an aspect of the present invention, a memory device includes: a base die; and a plurality of core dies stacked on the base die and connected to the base die through a plurality of through-silicon vias (TSV). Each of the plurality of core dies includes: a plurality of memory banks each having a plurality of rows corresponding to a plurality of row addresses, and the base die includes: a built-in self-test (BIST) circuit configured to select target banks from the plurality of memory banks in various combinations with respect to each of the plurality of row addresses, and to perform parallel tests on the target banks with respect to each of the plurality of row addresses; a comparator configured to compare data output from the target banks, and to output a fail signal according to a comparison result thereof; and a built-in analysis circuit configured to determine a defective bank by referring to the fail signal and target banks of each of the plurality of row addresses.

According to an aspect of the present invention, a memory device includes: a plurality of memory banks each having a plurality of rows corresponding to a plurality of row addresses; and a test circuit configured to: determine a target bank table indicating target banks selected from the plurality of memory banks, with respect to each of the plurality of row addresses; repeatedly perform an operation of writing the same data to the target banks, reading data stored in the target banks, and outputting a fail signal according to a result of comparing data read from the target banks, with respect to each of the plurality of row addresses; update fail information of each of the plurality of memory banks by referring to the fail signal and the target bank table; and determine a detective bank by referring to the fail information.

According to an aspect of the present invention, a method of manufacturing a memory device using a method of testing the memory device, the memory device including a plurality of memory banks each having a plurality of rows corresponding to a plurality of row addresses, the method of manufacturing the memory device includes providing the memory device to be tested. The method of testing the memory device includes: determining a target bank table indicating target banks selected from the plurality of memory banks, with respect to each of the plurality of row addresses; repeatedly performing an operation of writing the same data to the target banks, reading data stored in the target banks, and outputting a fail signal according to a result of comparing data read from the target banks with respect to each of the plurality of row addresses; updating fail information of each of the plurality of memory banks by referring to the fail signal and the target bank table; and determining a detective bank by referring to the fail information.

A memory device and a test method for the memory device according to an example embodiment of the present disclosure may perform parallel tests on target banks selected from a plurality of memory banks in various combinations, and specify a defective bank among the plurality of memory banks by combining parallel test results thereof.

In a memory device and a test method for the memory device according to an example embodiment of the present disclosure, since the comparator can compare data output from target banks and a built-in analysis circuit can analyze a detective bank using a fail signal output from the comparator, overhead for analyzing test results may be mitigated.

The aspects to be solved by the present disclosure are not limited to the above-mentioned aspects, and other aspects not mentioned herein will be clearly understood by those skilled in the art from the following description.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a diagram illustrating a memory system according to an example embodiment of the present disclosure;

FIG. 2 is a diagram illustrating a memory device according to an example embodiment of the present disclosure;

FIG. 3 is an operation timing diagram of a comparator according to an example embodiment of the present disclosure;

FIGS. 4A and 4B are diagrams illustrating a method for selecting a target bank according to an example embodiment of the present disclosure;

FIG. 5 is a flowchart illustrating a method of testing a memory device according to an example embodiment of the present disclosure;

FIG. 6 is a diagram illustrating a BIRA circuit according to an example embodiment of the present disclosure;

FIGS. 7A and 7B are diagrams illustrating a method for detecting a defective bank according to an example embodiment of the present disclosure;

FIGS. 8A and 8B are diagrams illustrating a method for detecting a defective bank according to an example embodiment of the present disclosure;

FIG. 9 is a diagram illustrating a BIRA circuit according to an example embodiment of the present disclosure;

FIG. 10 is a diagram illustrating a memory device according to an example embodiment of the present disclosure;

FIGS. 11A and 11B are diagrams illustrating a memory device according to an example embodiment of the present disclosure in detail; and

FIG. 12 is a block diagram illustrating a system to which a memory device according to an example embodiment of the present disclosure is applied.

### DETAILED DESCRIPTION

Hereinafter, example embodiments of the present disclosure will be described with reference to the accompanying drawings.

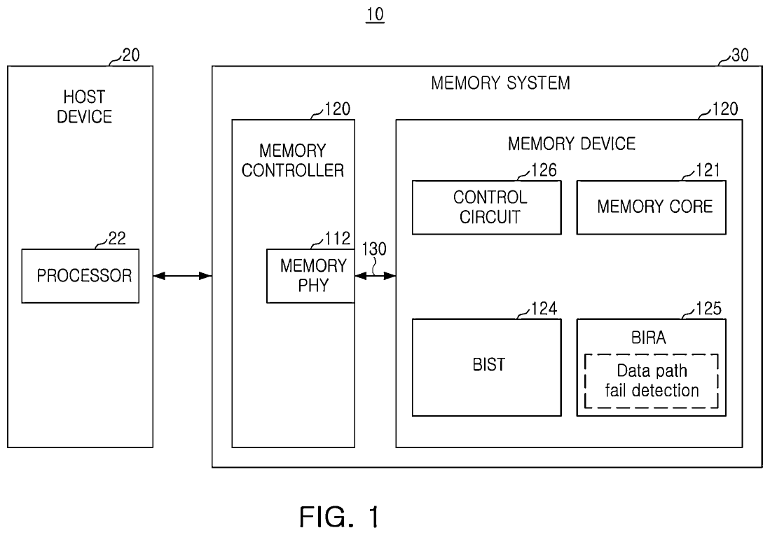

FIG. 1 is a diagram illustrating a memory system according to an example embodiment of the present disclosure.

Referring to FIG. 1, a system 10 may be a data center including dozens of host devices or servers. According to some example embodiments, the system 10 may be, for example, a computing device such as a laptop computer, a desktop computer, a server computer, a workstation, a portable communication terminal, a personal digital assistant (PDA), a portable multimedia player (PMP), a smartphone, a tablet PC and other suitable computers, a virtual machine, or a virtual computing device thereof. Alternatively, the system 10 may be some of the components included in a computing system such as a graphics card.

The system 10 has a number of hardware configurations described below more specifically with reference to FIG. 1, but the present invention is not limited thereto. The system 10 may include a host device 20 and a memory system 30. The host device 20 and the memory system 30 may be connected to each other according to various standard interfaces.

The host device 20 includes a processor 22 and may perform an operating system (OS) and/or various application programs. The processor 22 may be communicatively connected to the memory system 30. The memory system 30 connected to the processor 22 may be referred to as a system memory.

The processor 22 is a functional block performing a general computer operation in the system 10, and may be a central processing unit (CPU), a digital signal processor (DSP), a network processor, an application processor (AP), or any type of processor such as another device for executing a code. The processor 22 may be configured to execute instructions or software, firmware, or a combination thereof that can be executed with one or more machines. The processor 22 may include any number of processor cores. For example, the processor 22 may include a single-core or a multi-core such as a dual-core, a quad-core, and a hexa-core. FIG. 1 illustrates the system 10 including one processor 22, but according to an example embodiment, the system 10 may include a plurality of processors.

The memory system 30 may include a memory controller 110, a memory device 120, and a memory interface 130. The memory controller 110 may control a memory access operation (e.g., a write operation or a read operation) for the memory device 120 in response to a request from the host device 20 connected to the memory system 30. The memory device 120 may be used as a working memory for recording or loading data used for an operation of the processor 22. A memory system 30 including one memory device 120 is illustrated in FIG. 1, but according to an example embodiment, the memory system 30 may include a plurality of memory devices.

The memory interface 130 is illustrated as being connected as a single signal line between the memory controller 110 and the memory device 120 for simplicity of the drawing, but may actually be connected through a plurality of signal lines. The memory interface 130 includes connectors for connecting the memory controller 110 and the memory device 120, and the connectors may be implemented as pins, balls, signal lines, or other hardware components. For example, a clock signal CLK, a command/address signal CMD/ADDR and data DQ may be transmitted and received between the memory controller 110 and the memory device 120 through the memory interface 130. The memory interface 130 may be implemented as one channel including a plurality of signal lines, or may be implemented as a plurality of channels. The memory interface 130 may be referred to as a channel, and in the following embodiments, the terms “memory interface 130” and “channel” may be interchangeably used.

The memory controller 110 may access the memory device 120 by a memory request from the processor 22, and may be provided with a system physical address for memory access. The memory controller 110 may include a memory physical layer interface, that is, a memory PHY 112 for memory interfacing such as selecting a row and a column corresponding to a memory cell, recording data in the memory cell, or reading the recorded data from the memory cell.

The memory PHY 112 may take many shapes of actual physical implementation of the memory controller 110 performing the functions illustrated above. For example, the memory controller 110 may include physical configurations for exchanging data with the memory device 120, and may include at least one transmitter and at least one receiver. The memory controller 110 may include one or more hardware components (e.g., an analog circuit and a logic circuit). The memory controller 110 may be implemented as a program code of software and/or firmware. The memory controller 110 may be commonly integrated into the processor(s) 22 to ensure consistent access to the memory device(s) 120 by the processor(s) 22.

The memory device 120 may be a DRAM device. However, the scope of the present invention is not limited thereto, and the memory device 120 may be any one of volatile memory devices such as a synchronous DRAM (SDRAM), a double data rate (DDR SDRAM), a low power double data rate SDRAM (LPDDR SDRAM), a graphics double data rate SDRAM (GDDR SDRAM), a DDR2 SDRAM, a DDR3 SDRAM, a DDR4 SDRAM, a DDR5 SDRAM, a wide I/O DRAM, a high bandwidth memory (HBM), and a hybrid memory cube (HMC). According to another example embodiment, the memory device 120 may be any one of a plurality of memory devices mounted in a memory module. The memory module may be implemented as an Unbuffered Dual In-line Memory Module (UDIMM), a Registered DIMM (RDIMM), a Load Reduced DIMM (LRDIMM), a Fully Buffered DIMM (FBDIMM), a Small Outline DIMM (SODIMM), or the like.

The memory device 120 may include a memory core 121, a built-in self-test (BIST) circuit 124, a built-in redundancy analysis (BIRA) circuit 125, and a control circuit 126.

The memory core 121 may include a plurality of memory cell arrays. Each of a plurality of memory cell arrays may constitute a memory bank. Each of the plurality of memory cells may be formed of a DRAM cell including a single access transistor and a single storage capacitor. Each of the memory cell arrays may include normal memory cells and redundancy memory cells.

The control circuit 126 may control access to the memory core 121 based on a command and an address received by the memory device 120. For example, the control circuit 126 may control reading, writing, and refreshing operations of the memory core 121 based on a command and an address received through the memory interface 130.

In addition, the control circuit 126 may control a test of the memory device 120 in conjunction with the BIST circuit 124, and control an analysis of test results of the memory device 120 in conjunction with the BIRA circuit 125.

The BIST circuit 124 may perform the test of the memory device 120. Specifically, the BIST circuit 124 may test whether there is a defective memory cell in the memory core 121 or test whether there are defects in a data path of the memory device 120. For example, the BIST circuit 124 may perform the test by writing data to the memory core 121 and reading the written data from the memory core 121.

The BIRA circuit 125 may analyze a test result performed by the BIST circuit 124. Specifically, the BIRA circuit 125 may specify an address of the defective memory cell of the memory core 121 and repair the defective memory cell with a redundancy memory cell. Furthermore, when defects are detected in the data path, the BIRA circuit 125 may specify the data path in which the defects are detected. A circuit for analyzing the defects in the data path in the BIRA circuit 125 may be referred to as a built-in analysis circuit.

Meanwhile, the memory device 120 may support bank interleaving for accessing rows specified by the same row address in parallel in each of a plurality of memory banks. When the memory device 120 supports the bank interleaving, the BIST circuit 124 may perform a parallel test to test the plurality of memory banks. The parallel test may be a test for writing the same data pattern to rows specified by the same row address of the plurality of memory banks and determining a pass or fail according to whether the data patterns match by comparing the data patterns read from the rows.

Overhead may occur if the BIRA circuit 125 needs to detect defects in the memory bank by comparing the data patterns read from the plurality of banks with each other and specify a bank address of a defective memory bank. As a frequency of the data signal increases with an increase in the memory device 120 in speed and the number of memory banks increases according to the high capacitance of the memory device 120, the overhead for specifying the bank address may increase. Furthermore, connecting a plurality of data paths related to a plurality of banks to the BIRA circuit 125 may also be a large burden in terms of an area and performance of the semiconductor device 120.

According to an example embodiment of the present disclosure, the BIST circuit 124 may select two target banks in various combinations with respect to each of the plurality of row addresses and perform parallel tests on the target banks. Data patterns read from the two target banks may be compared in the comparator, and the comparator may provide a fail signal according to comparison results thereof to the BIRA circuit 125. The BIRA circuit 125 may specify a defective bank address by analyzing fail signals for each of the plurality of row addresses and various combinations of target banks.

According to an example embodiment of the present disclosure, the overhead for the BIRA circuit 125 for comparing the data patterns read from the plurality of banks with each other may be reduced, and a burden of connecting the plurality of data paths to the BIRA circuit 125 may be reduced.

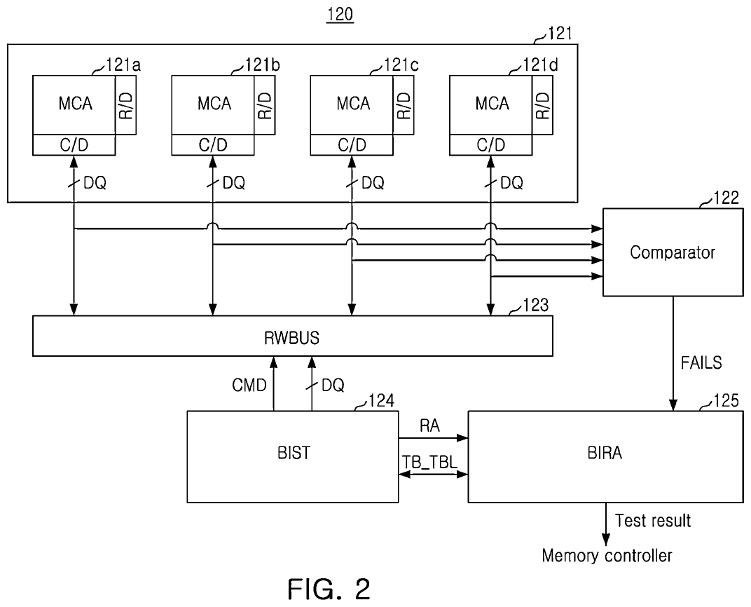

Hereinafter, a memory device according to an example embodiment of the present disclosure will be described in detail with reference to FIGS. 2, 3, 4A, 4B, 5, 6, 7A, 7B, 8A, 8B, 9, 10, 11A and 11B.

FIG. 2 is a diagram illustrating a memory device according to an example embodiment of the present disclosure.

A memory device 120 of FIG. 2 may correspond to the memory device 120 described with reference to FIG. 1. The memory device 120 may include a memory core 121, a comparator 122, a signal bus or a data bus 123, a BIST circuit 124, and a BIRA circuit 125. The control circuit 126 described with reference to FIG. 1 is omitted from FIG. 2.

The memory core 121 may include a plurality of memory banks 121a to 121d. Each of the plurality of memory banks 121a to 121d may include a memory cell array (MCA), a row decoder (R/D), a column decoder (C/D), and a sense amplifier (not shown). A memory cell included in the memory cell array MCA may be specified by a row address and a column address. The plurality of memory banks 121a to 121d may have the same row addresses and column addresses. For example, when bank interleaving is performed, rows specified by the row address may be accessed sequentially in each of the plurality of memory banks 121a to 21d based on a single row address.

Meanwhile, in an example of FIG. 2, the memory core 121 may include four memory banks 121a to 121d, but the number of memory banks in the present invention is not limited thereto.

The data bus 123 may provide a data path between the plurality of memory banks 121a to 121d and a memory interface 130. FIG. 2 illustrates a data line DQ between a data bus 123 and the plurality of memory banks 121a to 121d.

The BIST circuit 124 may provide a write command and a read command to test a data path of a plurality of memory banks 121a to 121d.

According to an example embodiment of the present disclosure, the BIST circuit 124 may select two target banks for a parallel test, with respect to each of a plurality of row addresses. The target banks may be selected in various combinations with respect to each of the plurality of row addresses. The BIST circuit 124 may store information into a target bank table TB_TBL indicating a mapping of row addresses and target banks. In an embodiment, the target bank table TB_TBL may be included in the BIST circuit 124 or the BIRA circuit 125.

The BIST circuit 124 may perform parallel tests on the plurality of memory banks 121a to 121d, by referring to the target bank table TB_TBL. Specifically, the BIST circuit 124 may control the same data pattern to be written to rows specified by the row address, in the target banks corresponding to a certain row address, and may perform the parallel tests for controlling the data stored in the rows to be read, with respect to each of the plurality of row addresses.

The data read from the target banks may be provided to the comparator 122. The comparator 122 may compare data provided from two target banks and output a fail signal FAILS according to comparison results thereof. For example, the fail signal FAILS may be a flag signal. Specifically, the comparator 122 may compare first data output from a first target bank with second data output from a second target bank for each bit, and output a fail signal FAILS by toggling a flag signal when the first data and the second data are different from each other by even one bit.

When the BIST circuit 124 performs parallel tests on the plurality of row addresses, fail signals FAILS corresponding to each of the plurality of row addresses may be sequentially output from the comparator 122.

The BIRA circuit 125 may determine a defective bank with defects in a data path based on a row address RA, a fail signal FAILS, and a target bank table TB_TBL, and output test results to an external memory controller. Specifically, the BIRA circuit 125 may determine whether the fail signal FAILS has occurred when performing a parallel test on which target banks based on the row address RA, the fail signal FAILS, and the target bank table TB_TBL. Depending on whether the fail signal FAILS occurs according to various combinations of target banks, it may be determined which memory bank among the plurality of memory banks 121a to 121d is tested to generate the fail signal FAILS. Furthermore, a memory bank that causes an occurrence of the fail signal FAILS may be determined as a defective bank.

According to an example embodiment of the present disclosure, the BIRA circuit 125 may determine the defective bank using the fail signal FAILS having a relatively low frequency instead of using a data signal DQ having a high frequency, thereby mitigating the overhead of the BIRA circuit 125.

Furthermore, since the comparator 122 may include a plurality of XOR circuits, the comparator 122 may be implemented in a relatively simple and repetitive structure. The plurality of XOR circuits forming the comparator 122 may be disposed adjacently to the data lines DQ as compared to the BIRA circuit 125. Accordingly, the structure of the comparator 122 may reduce an area and performance burdens of the semiconductor device 120 as compared to a case in which the data lines DQ are directly connected to the BIRA circuit 125.

Hereinafter, frequencies of the data signal DQ and the fail signal FAILS will be briefly described.

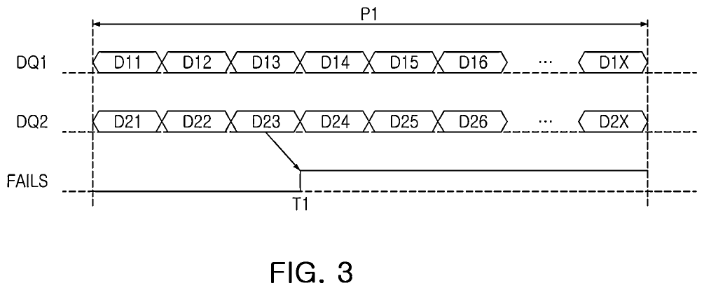

FIG. 3 is an operation timing diagram of a comparator according to an example embodiment of the present disclosure.

During a first period P1 in which parallel tests are performed on the first target bank and the second target bank selected with respect to a single row address, the comparator 122 described with reference to FIG. 2 may compare the first data output from the first target bank with the second data output from the second target bank.

Referring to FIG. 3, first data signals D11 to D1X output from a first data line DQ1 connected to the first target bank, and second data signals D21 to D2X output from a second data line DQ2 connected to the second target bank may be sequentially compared.

The first data signals D11 to D1X and the second data signals D21 to D2X may be compared in real time in an order in which these signals are received. The first data line DQ1 and the second data line DQ2 may transmit signals in synchronization with high frequencies, for example, frequencies of thousands of MHz.

When even one bit of the first data signals D11 to D1X and the second data signals D21 to D2X is different from each other, the comparator 122 may output a fail signal FAILS. Specifically, the fail signal FAILS may be initialized to a logic low state, and when a different bit is detected as a result of comparing the first data signals D11 to D1X and the second data signals D21 to D2X, the fail signal FAILS may be toggled to a logic high state, thus outputting the fail signal FAILS. For example, when a first data signal D13 and a second data signal D23 are detected to be different at a first time point T1, the fail signal FAILS at the first time point T1 may be toggled from the logic low state to the logic high state, a logical state of the fail signal FAILS may be maintained until it is initialized in a next cycle.

Referring to FIG. 3, the fail signal FAILS may have a lower frequency than those of the first data signals D11 to D1X and the second data signals D21 to D2X. Accordingly, overhead of a BIRA circuit for detecting a defective bank by processing a fail signal FAILS may be mitigated.

Hereinafter, a method of selecting target banks by a BIST circuit is described in detail so that the BIRA circuit may detect the defective bank based on the fail signal FAILS.

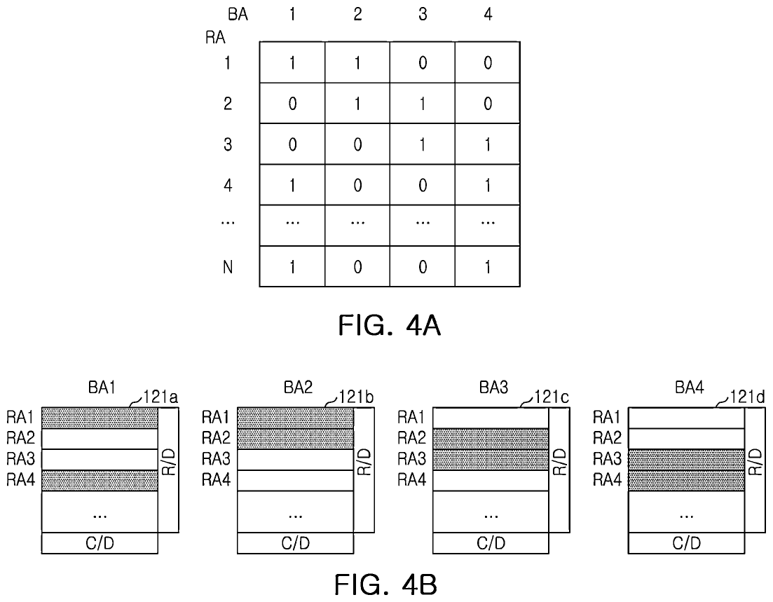

FIGS. 4A and 4B are diagrams illustrating a method for selecting a target bank according to an example embodiment of the present disclosure.

FIG. 4A is a diagram illustrating a bank address BA of a memory bank selected as target banks, in each of a plurality of row addresses RA. In FIG. 4A, “1” indicates a memory bank selected as a target bank, and “0” may indicate a memory bank not selected as a target bank.

Target banks in each row address RA may be selected in various combinations. However, in all row addresses RA, all memory banks may be selected as target banks at least twice. According to an example embodiment, when the number of row addresses RA is sufficiently large, all possible combinations of target banks may be selected at least once.

FIG. 4B is a diagram illustrating rows in which parallel tests are performed in a plurality of banks 121a to 121d. In FIG. 4B, a shaded region represents rows in which the parallel tests are performed.

According to an example embodiment of the present disclosure, the parallel tests may be performed in the order of the row address RA. Referring to FIGS. 4A and 4B together, when a target bank address of a first row address RA1 is selected as first and second bank addresses BA1 and BA2, a parallel test may be performed on a first row of the first and second memory banks 121a and 121b. Furthermore, when a target bank address of a second row address RA2 is selected as second and third bank addresses BA2 and BA3, a parallel test may be performed on a second row of the second and third memory banks 121b and 121c. Similarly, parallel tests may be performed on the target banks for the remaining rows.

Meanwhile, in the plurality of memory banks 121a to 121d, a parallel test may not be performed on all rows. However, defects in a data path of the memory bank may cause errors in the data even if any row of the memory bank is accessed, and accordingly, even when parallel tests are performed on some rows, a defective bank may be detected by combining parallel test results.

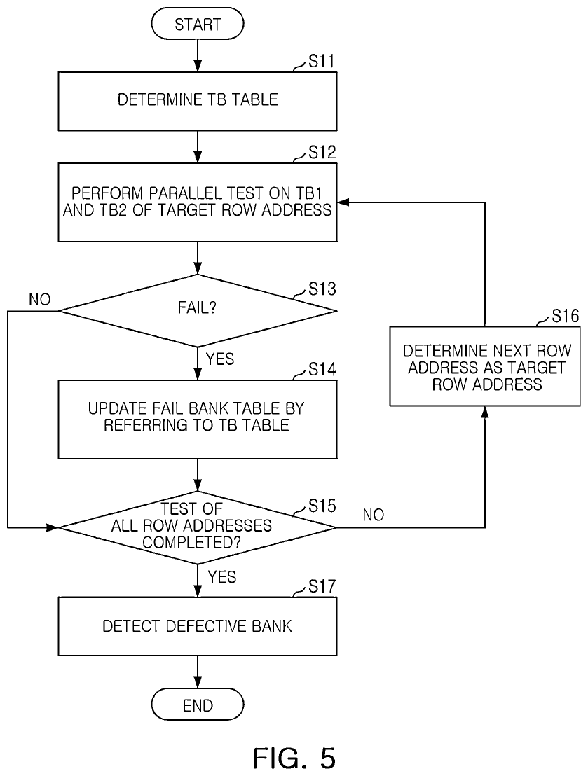

FIG. 5 is a flowchart illustrating a method of testing a memory device according to an example embodiment of the present disclosure.

Referring to FIG. 5, the method of testing a memory device may include a plurality of steps S11 to S17. In step S11, a target bank table may be determined. The target bank table may refer to a table for storing information on target banks selected with respect to each of a plurality of row addresses RA. Information of the target bank table may be permanently stored in a BIST circuit during manufacturing the memory device, or externally received at the BIST circuit during testing the memory device.

In step S12, parallel tests may be performed on target banks TB1 and TB2 of a target row address among a plurality of row addresses, and in step S13, it may be determined whether the parallel test fails.

When a parallel test result for the target row address is determined to be a fail (“Yes” in step S13), a fail bank table may be updated by referring to the target bank table in step S14. The fail bank table may store information on whether each of the memory banks fails, or store a fail count.

When the parallel test result for the target row address is determined to be a pass (“No” in step S13), it may be determined whether tests for all row addresses have been completed, in step S15.

When the tests for all row addresses have not been completed (“No” in step S15), a next row address of the target row address is determined as a new target row address in operation S16, and steps S12 to S15 may be repeatedly performed.

When the tests for all row addresses have been completed (“Yes” in step S15), a defective bank may be detected based on test results for all row addresses in step S17. After the defective bank is detected in step S17, the memory device may be saved by performing a repair operation thereon. A structure of the BIRA circuit for detecting the defective bank and a method for detecting the defective bank will be described in detail below.

Although not shown in FIG. 5, the flowchart may be a method of manufacturing a memory device using the method of testing the memory device. For example, the flowchart illustrating the method of manufacturing a memory device may include step S10 (not shown) before performing the steps S11 to S17. For example, in step S10, the memory device may be provided for testing. The memory device may be one of the memory devices 120 and 400 of FIGS. 1 and 4.

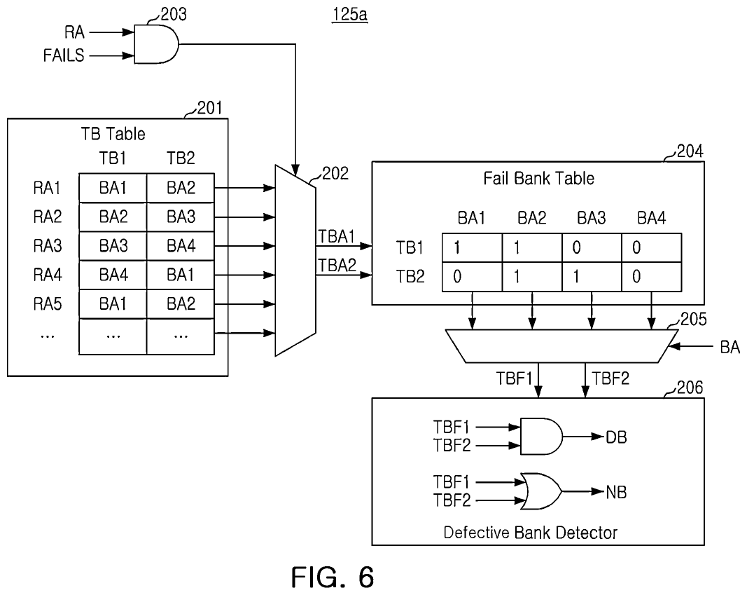

FIG. 6 is a diagram illustrating a BIRA circuit according to an example embodiment of the present disclosure.

A BIRA circuit 125a of FIG. 6 may correspond to the BIRA circuit 125 described with reference to FIG. 2. The BIRA circuit 125a may include a target bank table 201, a first selector 202, a fail address input gate 203, a fail bank table 204, a second selector 205, and a defective bank detector 206.

The target bank table 201 may store information on target banks TB1 and TB2 of each of a plurality of row addresses (RA1, RA2, RA3, RA4, RA5, . . . ). In an embodiment, the target bank table 201 may include latches, a static RAM (SRAM), or registers. For example, the information on target banks TB1 and TB2 of each of a plurality of row addresses may be stored in the latches, the SRAM, or the registers of the target bank table 201. The target banks TB1 and TB2 may include a first target bank TB1 and a second target bank TB2. In an example of FIG. 6, the first target bank TB1 and the second target bank TB2 may be distinguished from each other. For example, a selection of a first memory bank and a second memory bank as the first target bank TB1 and the second target bank TB2, respectively, and a selection of the second memory bank and the first memory bank as the first target bank TB1 and the second target bank TB2, respectively, may be distinguished.

In the example of FIG. 6, the target banks TB1 and TB2 may be selected to interlock with each other between consecutive row addresses. For example, in previous and subsequent row address of any consecutive row addresses, a first target bank of the subsequent row address may be selected as the same memory bank as a second target bank of the previous row address, and a second target bank of the subsequent row address may be selected as a memory bank different from a first target bank of the previous row address. However, the present invention is not limited thereto, and target banks of various combinations may be selected in various order.

The first selector 202 may output selected target bank addresses TBA1 and TBA2 in response to an input of a fail address input gate 203. The fail address input gate 203 may output a row address RA output from a BIST circuit 124 described with reference to FIG. 2, in response to a fail signal FAILS. That is, the fail address input gate 203 may input a row address RA determined as a fail among row addresses on which the parallel test has been performed, to the first selector 202.

The first selector 202 may output the target bank addresses TBA1 and TBA2 corresponding to the row address RA among the bank addresses of the target banks TB1 and TB2. For example, when a first row address RA1 is input from the fail address input gate 203, the first selector 202 may output first and second bank addresses BA1 and BA2 which are target bank addresses of the first row address RA1.

The fail bank table 204 may store information on whether or not a fail occurs for each bank address. In example embodiments, the fail bank table 204 may include latches, an SRAM, or registers. For example, the information on whether or not a fail occurs for each bank address may be stored in the latches, the SRAM, or the registers of the fail bank table 204. In the example of FIG. 6, the fail bank table 204 may store information on whether a fail occurs in a case in which the bank address is selected as the first target bank TB1 and in a case in which the bank address is selected as the second target bank TB2, respectively. In the fail bank table 204, “1” may indicate a bank address in which the fail has occurred, and “0” may indicate a bank address in which the fail has not occurred. The fail bank table 204 may be updated based on the target bank addresses TBA1 and TBA2 received from the first selector 202.

In response to an input of a bank address BA, the second selector 205 may output information on which the fail occurs, by corresponding to the input bank address. The information on whether the fail occurs may include first and second target bank flags TBF1 and TBF2 indicating whether the fail occurs in a case in which the input bank address is selected as the first target bank TB1 and in a case in which the input bank address is selected as the second target bank TB2, respectively.

The defective bank detector 206 may determine whether a bank corresponding to the input bank address is a defective bank by combining logical values of the first and second target bank flags TBF1 and TBF2. For example, a bank in which values of both the first and second target bank flags TBF1 and TBF2 are ‘1’ may be determined as a defective bank DB, and a bank in which any one of values of the first and second target bank flags TBF1 and TBF2 is ‘1’ may be determined as a noise bank NB having a possibility of defects. For example, the defective bank detector 206 may output a defective flag determined as a defective bank DB or a noise bank NB to the memory controller 110.

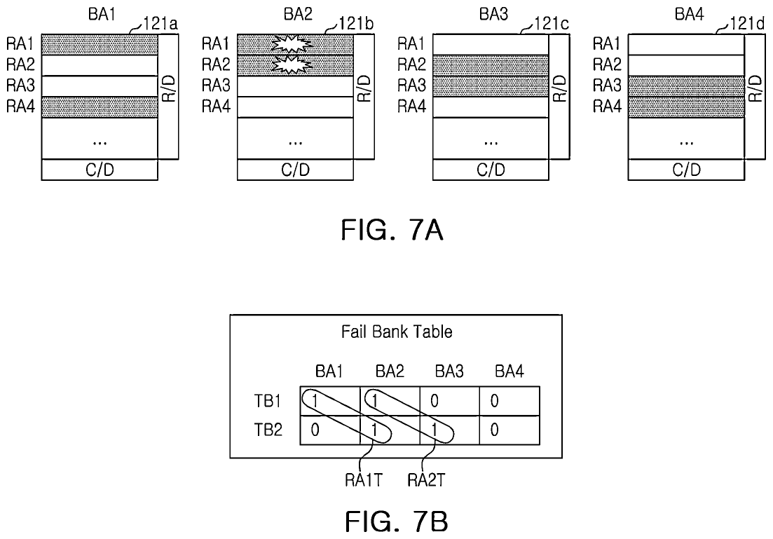

FIGS. 7A and 7B are diagrams illustrating a method for detecting a defective bank according to an example embodiment of the present disclosure.

FIG. 7A and FIG. 7B illustrate results of parallel tests when there is a defect in a data path of a second bank 121b among a plurality of memory banks 121a to 121d. Specifically, when there is a permanent defect in a data path of any memory bank, errors may be included in data read from the memory bank. Due to the defect of the second bank 121b, a defect test RA1T of the first and second banks 121a and 121b with respect to a first row address RA1 may be determined as a fail, and a defect test RA2T of the second and third banks 121b and 121c with respect to a second row address RA2 may be determined as a fail. A fail bank table 204 may be updated according to a result of the defect tests RA1T and RA2T.

In an example of FIG. 7B, the second bank address BA2 may be determined as a fail in both the case of the first target bank TB1 and the case of the second target bank TB2. Accordingly, the second bank 121b corresponding to the second bank address BA2 may be determined as a defective bank.

On the other hand, the first bank address BA1 and the third bank address BA3 may be determined as the fail only when tested together with the second target bank address BA2, and in other cases, the first bank address BA1 and the third bank address BA3 may be determined as a pass. Accordingly, the first and third banks 121a and 121c corresponding to the first and third bank addresses BA1 and BA3 may be determined as noise banks.

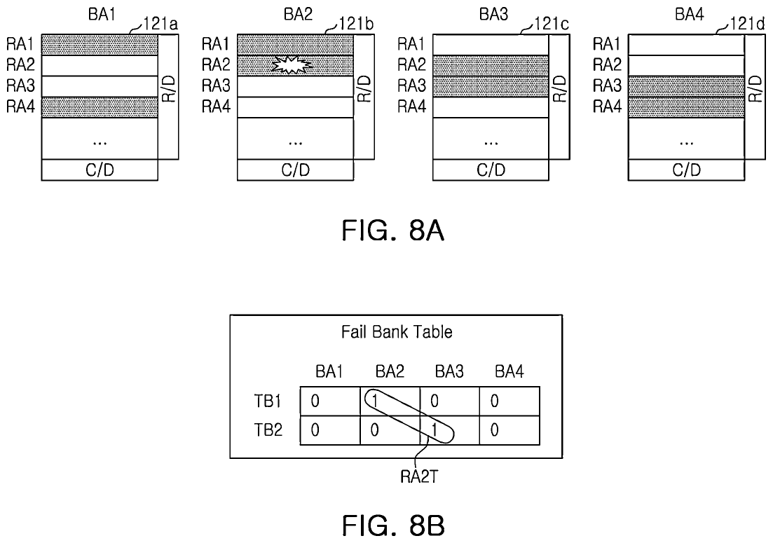

FIGS. 8A and 8B are diagrams illustrating a method for detecting a defective bank according to an example embodiment of the present disclosure.

FIGS. 8A and 8B illustrate results of parallel tests when there is no defect in a data path of a plurality of memory banks 121a to 121d. Even when there is no permanent defect in a data path of any memory bank, data read from the memory bank may include intermittent errors due to various factors such as an order in which rows are read from the memory bank, a temperature of the memory device, and a voltage applied to the memory device.

For example, during a defect test RA2T of the second and third banks 121b and 121c with respect to a second row address RA2, an error may occur intermittently in the second bank 121b, and the defect test RA2T may be determined as a fail.

Second and third bank addresses BA2 and BA3 may be determined as a fail in only one test result, and in other cases, the second and third bank addresses BA2 and BA3 may be determined as a pass. Accordingly, the second and third banks 121b and 121c corresponding to the second and third bank addresses BA2 and BA3 may be determined as noise banks.

Meanwhile, in the example of FIGS. 7A, 7B, 8A and 8B, when first and third banks 121a and 121c are tested in parallel together with the second bank 121b, although no error has occurred in a data path of the first and third banks 121a and 121c, the first or third bank 121a or 121c may be determined as a noise bank.

According to an example embodiment of the present disclosure, target banks may be selected so that parallel tests are performed on all combinations of target banks, and a fail bank table may count the number of fail occurrences of each of the memory banks. Furthermore, the defective banks and the noise banks may be determined based on the fail occurrence count, thereby improving the accuracy of defect detection of memory banks.

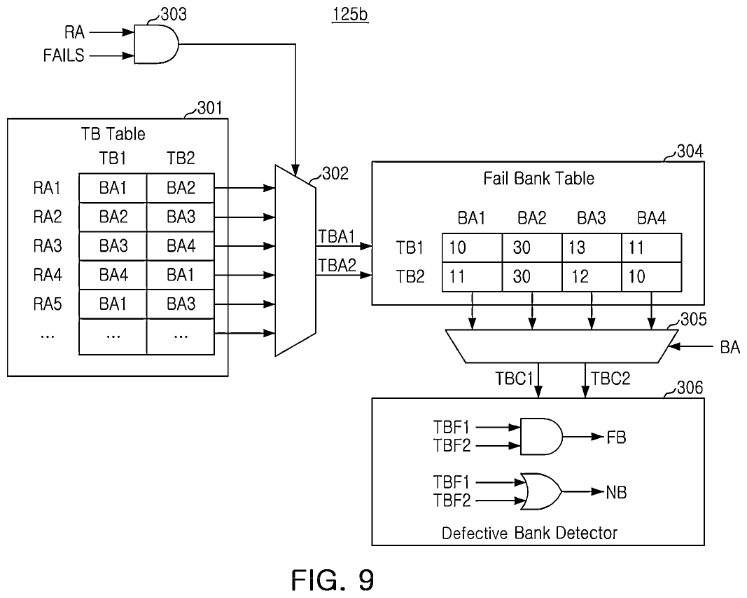

FIG. 9 is a diagram illustrating a BIRA circuit according to an example embodiment of the present disclosure.

A BIRA circuit 125b of FIG. 9 may correspond to the BIRA circuit 125 described with reference to FIG. 2. The BIRA circuit 125a may include a target bank table 301, a first selector 302, a fail address input gate 303, a fail bank table 304, a second selector 305, and a defective bank detector 306. The BIRA circuit 125b of FIG. 9 may have a structure similar to that of the BIRA circuit 125a of FIG. 6, except that the fail bank table 304 counts the number of fail occurrences for each bank address. Hereinafter, the BIRA circuit 125b of FIG. 9 will be described focusing on a difference from the BIRA circuit 125a of FIG. 6.

In the example of FIG. 9, parallel tests may be performed at an even number of times for all possible combinations of target banks, and a plurality of bank addresses BA1 to BA4 may be evenly selected as first and second target banks TB1 and TB2.

When a plurality of bank addresses BA1 to BA4 are evenly selected, a fail count may be concentrated on a memory bank that has an actual defect, and the fail count of the remaining memory banks may be distributed. For example, when there is a defect in a data path of the second memory bank, results of parallel tests for the first and second memory banks, parallel tests for the second and third memory banks, and parallel tests for the second and fourth memory banks may all be determined as fails. As a result of the parallel tests, the fail count of the second memory bank may be counted several times, but the fail count of the first, third and fourth memory banks may be counted only once. Accordingly, memory banks having actual defects may be more accurately distinguished.

In response to a signal of the bank address BA, first and second target bank counts TBC1 and TBC2 indicating each of fail counts in a case in which an input bank address is selected as a first target bank TB1 and in a case in which an input bank address is selected as a second target bank TB2 may be input to the defective bank detector 306.

The defective bank detector 306 may determine whether a bank corresponding to the input bank address is a defective bank by combining logical values of first and second target bank flags TBF1 and TBF2. Each of the first and second target bank flags TBF1 and TBF2 may be set according to whether each of the first and second target bank counts TBC1 and TBC2 is greater than or equal to a threshold value. That is, when both the first and second target bank counts TBC1 and TBC2 are greater than or equal to the threshold value, the memory bank may be determined as a defective bank, and when any one of the first and second target bank counts TBC1 and TBC2 is greater than or equal to the threshold value, the memory bank may be determined as a noise bank.

According to an example embodiment of the present disclosure, the memory device may perform a parallel test on two target banks selected from a plurality of memory banks in various combinations. For each parallel test, only data output from two target banks may be compared to each other, thus mitigating overhead for data comparison, and a bank address of the defective bank may be specified by combining parallel test results.

Meanwhile, when a memory device is implemented as a high bandwidth memory (HBM) including thousands of data lines, the overhead of the BIRA circuit for specifying the bank address of the defective bank may be greatly mitigated. Hereinafter, a case in which the memory device according to an example embodiment of the present disclosure is implemented as the HBM will be described in detail.

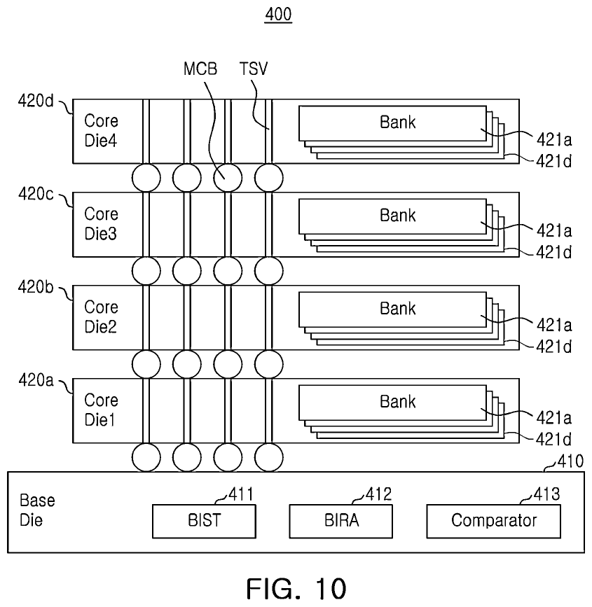

FIG. 10 is a diagram illustrating a memory device according to an example embodiment of the present disclosure.

A memory device 400 may be implemented as an HBM. Referring to FIG. 10, the memory device 400 may include a base die 410 and a plurality of core dies 420a to 420d.

The plurality of core dies 420a to 420d may be stacked on the base die 410, may be electrically connected to the base die 410 through a plurality of through-silicon vias or through-substrate vias (TSV). The plurality of TSVs may be electrically connected through micro-bumps (MCB) formed between the plurality of core dies 420a to 420d and the base die 410.

Each of the plurality of core dies 420a to 420d may include a plurality of memory banks 421a to 421d. The plurality of memory banks 421a to 421d may have a structure similar to that of the memory banks 121a to 121d described with reference to FIG. 2.

The base die 410 may transmit a control signal to the plurality of core dies 420a to 420d, and may exchange data with the plurality of core dies 420a to 420d. The plurality of memory banks 421a to 421d may exchange data with the outside through the base die 410. Accordingly, a BIST circuit 411, a BIRA circuit 412, and a comparator 413 may be included in the base die 410 to test a data path. However, the present invention is not limited thereto, and the comparator 413 may be included in each of the plurality of core dies 420a to 420d.

The BIST circuit 411, the BIRA circuit 412, and the comparator 413 may correspond to the BIST circuit 124, the BIRA circuit 125, and the comparator 123 described with reference to FIG. 2. According to an example embodiment of the present disclosure, the BIST circuit 411 may select target banks in various combinations for each of a plurality of row addresses and may perform parallel tests on the target banks, and the comparator 413 may provide a fail signal to the BIRA circuit 413 according to parallel test results. The BIRA circuit 413 may detect a defective bank by analyzing a combination of the fail signal and the target banks.

Meanwhile, in order to select the core die of the memory device 400, a die address SID may be further defined. In order to select target banks from a plurality of memory banks 421a to 421d included in the plurality of core dies 420a to 420d, the die address SID as well as the bank address BA may be further defined.

According to an example embodiment, the parallel tests and defective bank detection as described with reference to FIGS. 2, 3, 4A, 4B, 5, 6, 7A, 7B, 8A, 8B and 9 may be sequentially performed on the plurality of core dies 420a to 420d. When the parallel tests and the defective bank detection are performed sequentially, the complexity of the target bank table and the fail bank table may be mitigated as compared to a case of performing the parallel tests and the defective bank detection on all of the plurality of core dies 420a to 420d.

According to an example embodiment of the present disclosure, the BIRA circuit 412 may detect a defective bank without directly comparing data signals having high frequencies received from a plurality of data lines, thereby mitigating the overhead of the BIRA circuit 412.

In order to reduce the area and performance burden of the memory device 400, the comparator 413 may be disposed closer to the data lines than the BIRA circuit 412.

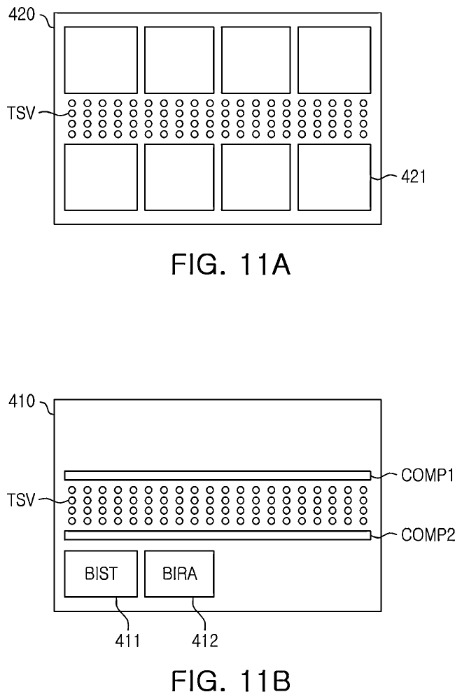

FIGS. 11A and 11B are diagrams illustrating a memory device according to an example embodiment of the present disclosure in detail.

FIG. 11A is a top view of a core die 420 that may correspond to any one of the core dies 420a to 420d described with reference to FIG. 10, and FIG. 11B is a top view of the base die 410 described with reference to FIG. 10.

Referring to FIG. 11A, the core die 420 may include a plurality of memory banks 421 and a plurality of TSVs. In an example of FIG. 11A, the plurality of TSVs may penetrate in a center of the core die 420, and the plurality of memory banks 421 may be disposed adjacently to the plurality of TSVs capable of providing a data line.

Referring to FIG. 11B, the base die 410 may include a BIST circuit 411, a BIRA circuit 412, and a plurality of comparison units COMP1 and COMP2. The plurality of comparison units COMP1 and COMP2 may form a comparator 413 as described with reference to FIG. 10. Other control circuits that may be included in the base die 410 may be omitted.

In an example of FIG. 11B, the plurality of TSVs of the core die 420 may also penetrate the base die 410. Furthermore, the plurality of comparison units COMP1 and COMP2 may be disposed adjacently to the plurality of TSVs. The comparator 413 may be implemented in an XOR tree including a plurality of XOR circuits. The plurality of XOR circuits may be distributed around a plurality of data lines so as to be disposed adjacently to TSVs providing data lines to be compared.

When the memory device 400 is an HBM, the number of data lines included in the memory device 400 may reach thousands. The plurality of XOR circuits disposed adjacently to the plurality of data lines may perform a comparison operation involved in parallel tests, and only a fail signal generated as a result of the comparison operation may be provided to the BIRA circuit 412. Accordingly, the area and performance burden for connecting the plurality of data lines to the BIRA circuit 412 may be mitigated.

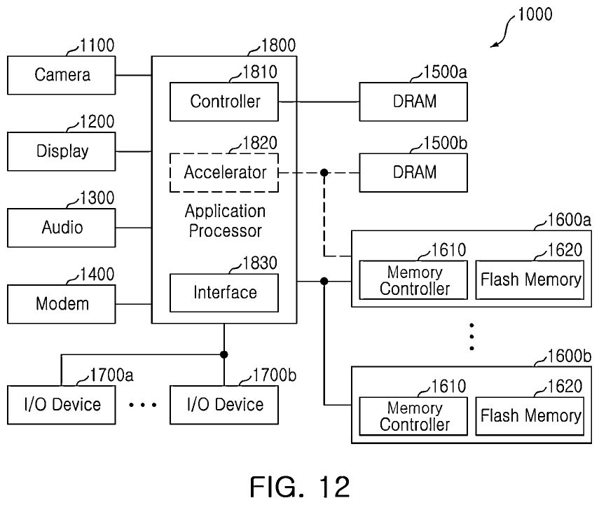

FIG. 12 is a block diagram illustrating a system to which a memory device according to an example embodiment of the present disclosure is applied.

Referring to FIG. 12, a system 1000 may include a camera 1100, a display 1200, an audio processing unit 1300, a modem 1400, DRAMs 1500a and 1500b, storage devices 1600a and 1600b, I/O devices 1700a and 1700b, and an application processor 1800 (hereinafter referred to as “AP”). The system 1000 may be implemented as a laptop computer, a mobile phone, a smart phone, a tablet personal computer (PC), a wearable device, a healthcare device, or an Internet of Things (IoT) device. In addition, the system 1000 may be implemented as a server or a personal computer.

The camera 1100 may capture a still image or a moving image under the control of a user, and may store the captured image/image data or transmit the same to the display 1200. The audio processing unit 1300 may process audio data included in the flash memory devices 1600a and 1600b or a content of a network. The modem 1400 may modulate and transmit signals for wired/wireless data transmission and reception, and may demodulate the signals so as to be restored to original signals at a receiving side. The I/O devices 1700a and 1700b may include devices configured to provide digital input and/or output functions, such as universal serial bus (USB) or storage, a digital camera, a secure digital (SD) card, a digital versatile disc (DVD), a network adapter, a touch screen and the like.

The AP 1800 may control an overall operation of the system 1000. The AP 1800 may control the display 1200 such that a portion of a content stored in the flash memory devices 1600a and 1600b is displayed on the display 1200. When a user input is received through the I/O devices 1700a and 1700b, the AP 1800 may perform a control operation corresponding to a user input. The AP 1800 includes an accelerator block as a dedicated circuit for computing Artificial Intelligence (AI) data, or may have an accelerator chip 1820 separately from the AP 1800. A DRAM 1500b may be additionally mounted on the accelerator block or the accelerator chip 1820. The accelerator is a functional block for specializing in performing specific functions of the AP 1800, and may include a GPU which is a functional block for specializing in performing graphic data processing, a natural processing unit (NPU) which is a block for specializing in performing an AI calculation and Inference, and a data processing unit (DPU) which is a block for specializing in data transmission.

The system 1000 may include a plurality of DRAMs 1500a and 1500b. The AP 1800 may communicate with the DRAMs 1500a and 1500b by controlling the DRAMs 1500a and 1500b through mode register (MRS) setting and a command that conform to the Joint Electron Device Engineering Council (JEDEC) standard, or by setting DRAM interface protocols to use company-specific functions such as low voltage/high speed/reliability and Cyclic Redundancy Check (CRC)/Error Correction Code (ECC) functions. For example, the AP 1800 may communicate with the DRAM 1500a through an interface complying with JEDEC standards, such as LPDDR4 and LPDDR5, and the accelerator block or the accelerator chip 1820 may communicate by setting a new DRAM interface protocol so as to control the DRAM 1500b for an accelerator having a higher bandwidth than that of the DRAM 1500a.

Although FIG. 12 illustrates only DRAMs 1500a and 1500b, the present invention is not limited thereto, and any memory, such as a phase RAM (PRAM), a static RAM (SRAM), a magnetic RAM (MRAM), a resistive RAM (RRAM), a ferroelectric RAM (FRAM), or a Hybrid RAM (HRAM), can be used as long as it satisfies a bandwidth, response speed, and voltage conditions of the AP 1800 or the accelerator chip 1820. The DRAMs 1500a and 1500b have relatively smaller latency and bandwidth than the I/O devices 1700a and 1700b or the flash memories 1600a and 1600b. The DRAMs 1500a and 1500b may be initialized at a power-on time of the system 1000, and may be used as a temporary storage place for an operating system and application data by loading the operating system and the application data therein, or may be used as an execution space for various software codes.

In the DRAMs 1500a and 1500b, four arithmetic operations such as addition/subtraction/multiplication/division, vector operations, address operations, or Fast Fourier Transform (FFT) operations may be performed. Furthermore, a function for performance used in inference may be performed in the DRAMs 1500a and 1500b. Here, the inference can be performed in a deep learning algorithm using an artificial neural network. The deep learning algorithm may include a training operation of learning a model through various data and an inference operation of recognizing data with the learned model. According to an example embodiment, an image captured by a user through the camera 1100 is signal-processed and stored in the DRAM 1500b, and the accelerator block or the accelerator chip 1820 may perform an AI data operation for recognizing data using the data stored in the DRAM 1500b and the function used for the inference.

Each of the DRAMs 1500a and 1500b may include a plurality of memory banks and may include the BIST circuit, the BIRA circuit, and the comparator as described with reference to FIGS. 1, 2, 3, 4A, 4B, 5, 6, 7A, 7B, 8A, 8B, 9, 10, 11A and 11B. Each of the DRAMs 1500a and 1500b may perform parallel tests of the selected target banks in various combinations with respect to a plurality of row addresses, and may detect a defective bank having a defect in the data path based on the combination of the target banks and the parallel test results for each of the plurality of row addresses.

The system 1000 may include a plurality of storage or the plurality of storage devices 1600a and 1600b having larger capacitance than the DRAMs 1500a and 1500b. The accelerator block or the accelerator chip 1820 may perform a training operation and an AI data calculation using the storage devices 1600a and 1600b. In an example embodiment, the storage devices 1600a and 1600b may more efficiently perform a training operation performed by the AP 1800 and/or the accelerator chip 1820 using a computing device provided in a memory controller 1610 and a computation of inference AI data. Each of the storage devices 1600a and 1600b may include the memory controller 1610 and a flash memory 1620. The storage devices 1600a and 1600b may store a picture captured through the camera 1100 or may store data transmitted to a data network. For example, the storage devices 1600a and 1600b may store Augmented Reality/Virtual Reality, High Definition (HD) or Ultra High Definition (UHD) content.

The present invention is not limited to the above-described embodiments and the accompanying drawings but is defined by the appended claims. Therefore, those of ordinary skill in the art may make various replacements, modifications, or changes without departing from the scope of the present invention defined by the appended claims, and these replacements, modifications, or changes should be construed as being included in the scope of the present invention.

What is claimed is:

1. A memory device comprising:
a plurality of memory banks each having a plurality of rows corresponding to a plurality of row addresses;
a built-in self-test (BIST) circuit configured to:
select a first target bank and a second target bank for each of the plurality of row addresses such that each of the plurality of memory banks is selected as the first target bank and the second target bank at least once, and
perform parallel tests on the first target bank and the second target bank for each of the plurality of row addresses;
a comparator configured to compare first data output from the first target bank and second data output from the second target bank, and to output a fail signal according to a comparison result thereof; and
a built-in analysis circuit configured to update a fail bank table indicating fail information of each of the plurality of memory banks, in response to the fail signal, and to determine a defective bank by referring to the fail bank table.

2. The memory device of claim 1, wherein in any previous row address and subsequent row address of any consecutive row addresses among the plurality of row addresses, a first target bank of the subsequent row address is identical to a second target bank of the previous row address, and a second target bank of the subsequent row address is different from a first target bank of the previous row address.

3. The memory device of claim 1, wherein the BIST circuit is configured to select a first target bank and a second target bank such that all combinations of the first target bank and the second target bank are selected from the plurality of row addresses.

4. The memory device of claim 1, wherein the comparator is configured to:
initialize the fail signal, and
toggle the fail signal when different bits are detected in the first data and the second data.

5. The memory device of claim 1, wherein the built-in analysis circuit is configured to:
obtain a target row address corresponding to the fail signal from the BIST circuit, and
update the fail bank table by referring to a target bank table including information of the first target bank and the second target bank selected for each of the plurality of row addresses.

6. The memory device of claim 1, wherein the fail bank table includes information on whether each fail occurs in a case in which each of the plurality of memory banks is a first target bank and in a case in which each of the plurality of memory banks is a second target bank.

7. The memory device of claim 6, wherein the built-in analysis circuit is configured to determine, as the defective bank, a memory bank in which the fail occurs in both the case of the first target bank and the case of the second target bank among the plurality of memory banks.

8. The memory device of claim 6, wherein the built-in analysis circuit is configured to determine, as a noise bank, a memory bank in which the fail occurs in either the case of the first target bank or the case of the second target bank among the plurality of memory banks.

9. The memory device of claim 6, wherein the fail bank table includes a plurality of latches for storing information on whether the fail occurs.

10. The memory device of claim 1, wherein the fail bank table includes each fail count information in a case in which each of the plurality of memory banks is a first target bank and in a case in which each of the plurality of memory banks is a second target bank.

11. The memory device of claim 10, wherein the built-in analysis circuit is further configured to determine, as the defective bank, a memory bank in which both a first fail count in the case of the first target bank and a second fail count in the case of the second target bank among the plurality of memory banks are greater than or equal to a threshold value.

12. The memory device of claim 11, wherein the built-in analysis circuit is further configured to determine, as a noise bank, a memory bank in which either the first fail count in the case of the first target bank or the second fail count in the case of the second target bank among the plurality of memory banks is greater than or equal to the threshold value.

13. The memory device of claim 1, wherein the fail bank table includes information on whether each fail occurs in a case in which each of the plurality of memory banks is a first target bank and in a case in which each of the plurality of memory banks is a second target bank, and
wherein the built-in analysis circuit comprises:
a target bank table configured to store information on the first target bank and the second target bank of each of the plurality of row addresses;
a first selector configured to output a first target bank address and a second target bank address of a target row address from the target bank table to the fail bank table, in response to the fail signal and the target row address;
a second selector configured to output information on whether fails of a first target bank and a second target bank corresponding to a bank address occur from the fail bank table, in response to the bank address of one of the plurality of memory banks; and
a defective bank detector configured to output a defective flag indicating whether the bank address corresponds to the defective bank by performing a logical operation for the information on whether the fail occurs.

14. The memory device of claim 1, wherein the BIST circuit is configured to perform the parallel tests by:
writing the same data to the first target bank and the second target bank, and
reading data stored in the first target bank and the second target bank.

15. The memory device of claim 1, wherein the comparator includes a plurality of XOR circuits, and
wherein the plurality of XOR circuits are disposed closer to a data path of the plurality of memory banks than the built-in analysis circuit.

16. The memory device of claim 1, wherein the built-in analysis circuit comprises:
a target bank table configured to store information on the first target bank and the second target bank of each of the plurality of row addresses, and
wherein the information of the target bank table is stored at a time of manufacturing the memory device or is received from outside the memory device.

17. A memory device comprising:
a base die; and
a plurality of core dies stacked on the base die and connected to the base die through a plurality of through-silicon vias (TSV),
wherein each of the plurality of core dies comprises:
a plurality of memory banks each having a plurality of rows corresponding to a plurality of row addresses, and
wherein the base die comprises:
a built-in self-test (BIST) circuit configured to:
select target banks from the plurality of memory banks in various combinations with respect to each of the plurality of row addresses, and
perform parallel tests on the target banks with respect to each of the plurality of row addresses;
a comparator configured to compare data output from the target banks, and to output a fail signal according to a comparison result thereof; and
a built-in analysis circuit configured to determine a defective bank by referring to the fail signal and target banks of each of the plurality of row addresses.

18. The memory device of claim 17, wherein the comparator includes a plurality of XOR circuits, and
wherein each of the plurality of XOR circuits is disposed adjacently to TSVs providing data lines to be compared among the plurality of TSVs.

19. The memory device of claim 17, wherein the BIST circuit is configured to sequentially perform the parallel tests for each of the plurality of row addresses with respect to the plurality of core dies.

20. A memory device comprising:
a plurality of memory banks each having a plurality of rows corresponding to a plurality of row addresses; and
a test circuit configured to:
determine a target bank table indicating target banks selected from the plurality of memory banks, with respect to each of the plurality of row addresses,
repeatedly perform an operation of writing the same data to the target banks, reading data stored in the target banks, and outputting a fail signal according to a result of comparing data read from the target banks, with respect to each of the plurality of row addresses,
update fail information of each of the plurality of memory banks by referring to the fail signal and the target bank table, and
determine a detective bank by referring to the fail information.
